(19) United States
(12) Patent Application Publication
(10) Pub. No.: US 2023/0178549 A1
(43) Pub. Date: Jun. 8, 2023

(54) STACKED FIELD EFFECT TRANSISTORS

(71) Applicant: International Business Machines Corporation, Armonk, NY (US)

(72) Inventors: Sung Dae SUK, Watervliet, NY (US); Timothy Mathew PHILIP, Albany, NY (US); Junli WANG, Slingerlands, NY (US); Dechao GUO, Niskayuna, NY (US); Chen ZHANG, Guilderland, NY (US)

(21) Appl. No.: 17/643,362

(22) Filed: Dec. 8, 2021

(51) Int. Cl. H01L 27/092; H01L 29/06; H01L 29/417; H01L 23/528; H01L 29/66; H01L 21/8238

(52) U.S. Cl. CPC H01L 27/092; H01L 21/823828; H01L 23/5286; H01L 27/0924; H01L 29/0665; H01L 29/41725; H01L 29/41791; H01L 29/66545

(57) ABSTRACT

Stacked field effect transistors are provided such having a first power rail; a second power rail; a first Field Effect Transistor (FET) having a first gate connected to the first power rail; a second FET having a second gate connected to the second power rail; and an insulator separating the first FET from the second FET, wherein the first power rail, the second power rail, the first FET, and the second FET are aligned on a shared axis, and wherein the first power rail and the second power rail are located on opposite sides of the device.

### BACKGROUND

The present invention relates to Field Effect Transistors (FETs), and more specifically, to a design for stacking FETS with reduced middle-of-line (MOL) resistances by using top and bottom power rails.

A FET is a type of transistor that controls the flow of current in a channel between a source and a drain via the control of voltage to a gate terminal to permit or block transmission between the source and the drain. When fabricating devices that include multiple FETs, as in a fin-type FET (also referred to as a FinFET or FINFET) or nanosheet (also referred to as a gate-all-around design, multi-bridge channel, or nanobeam) structure, the relative layouts of the power rails used to provide the activating voltage to the gates can affect the resistances experienced by the different FETs and induce unwanted capacitances.

### SUMMARY

According to one embodiment of the present invention, a device is provided that includes: a first power rail; a second power rail; a first Field Effect Transistor (FET) having a first gate connected to the first power rail; a second FET having a second gate connected to the second power rail; and an insulator separating the first FET from the second FET, wherein the first power rail, the second power rail, the first FET, and the second FET are aligned on a shared axis, and wherein the first power rail and the second power rail are located on opposite sides of the device.

According to one embodiment of the present invention, a method is provided that includes: forming a first channel region projecting in a first direction from a central insulator; forming a first gate on the first channel region to define a first Field Effect Transistor (FET); forming a second channel region projecting in a second direction, opposite to the first direction, from the central insulator; and forming a second gate on the second channel region to define a second FET.

According to one embodiment of the present invention, a device is provided that includes: a first Field Effect Transistor (FET) aligned on a first axis with a second FET located on opposite sides on a plane perpendicular to the first axis; a first power rail connected to the first FET along the first axis; and a second power rail connected to the second FET along the first axis, wherein the first power rail and the second power rail are located on opposite sides of the device.

### BRIEF DESCRIPTION OF THE SEVERAL VIEWS OF THE DRAWINGS

FIGS. 1A and 1B illustrate stacked layouts of Field Effect Transistors (FETs), according to embodiments of the present disclosure.

FIGS. 2A-2F illustrate gate contact positions relative to a stacked pair of FETs, according to embodiments of the present disclosure.

FIGS. 3A-3D illustrate a shared terminal layout of a pair of FETs, according to embodiments of the present disclosure.

FIG. 4 is a flowchart of a method for fabrication of a first FET in a stacked layout, according to embodiments of the present disclosure.

FIGS. 5A-5D illustrate several views of the structure during fabrication according to the method described in relation to FIG. 4, according to embodiments of the present disclosure.

FIGS. 6A-6J illustrate several views of the structure during fabrication according to the method described in relation to FIG. 4, according to embodiments of the present disclosure.

FIGS. 7A-7H illustrate several views of the structure during fabrication according to the method described in relation to FIG. 4, according to embodiments of the present disclosure.

FIG. 8 is a flowchart of a method for fabrication of a second FET in a stacked layout, according to embodiments of the present disclosure.

FIGS. 9A-9P illustrate several views of the structure during fabrication according to the method described in relation to FIG. 8, according to embodiments of the present disclosure.

### DETAILED DESCRIPTION

The present disclosure provides for stacked layouts for Field Effect Transistors (FETs) and methods of fabrication thereof. By aligning the FETs with one another in a stacked arrangement (e.g., located on opposite sides of an insulator), and placing the electrical contacts accordingly, the overall footprint of the FET cells can be reduced; allowing a greater number of transistors in a given area. Additionally, the behavior of the stacked FETs becomes more regular due to the ability to individually control or match the resistances experienced by the stack FETs and the various power or signal rails connected thereto.

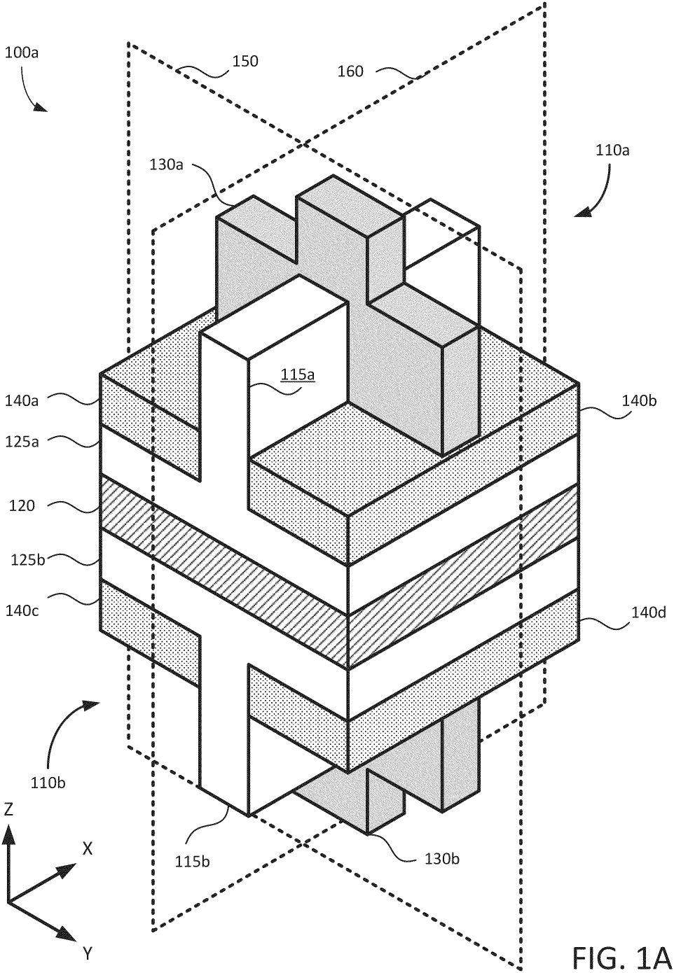

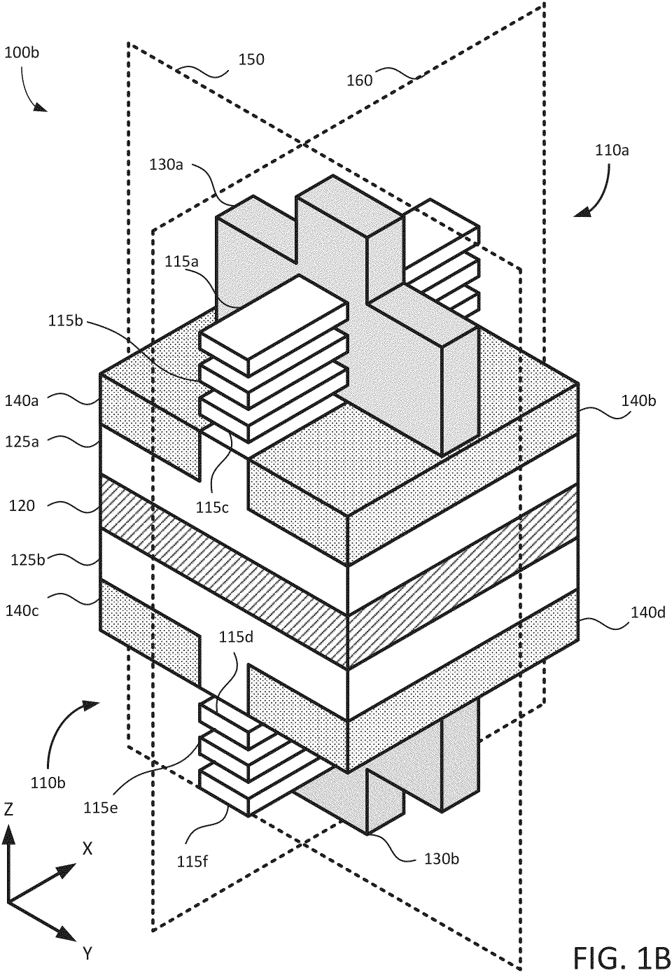

With reference now to FIGS. 1A and 1B, stacked layouts of FETs 110 (individually, FETs 110a-f) are shown, according to embodiments of the present disclosure. FIG. 1A illustrates a FINFET layout 100a (generally or collectively, layout 100), while FIG. 1B illustrates a nanosheet layout 100b. In each of the layouts 100, a first FET 110a is separated from a second FET 110b by an insulator 120, and the first FET 110a is stacked (in the Z direction) on top of the second FET 110b, and each FET 110 with a corresponding fin-type channel regions 115a-b (generally or collectively, channel region 115) protruding (in the Z direction) from a base substrate.

In FIG. 1B, the FETs 110a-b are illustrated using a series of nanosheet-type channel regions 115a-f that are stacked in alignment with one another. Although shown with three channel regions 115 each, in various embodiments, more or fewer channel regions 115 may be included in a nanosheet-type transistor.

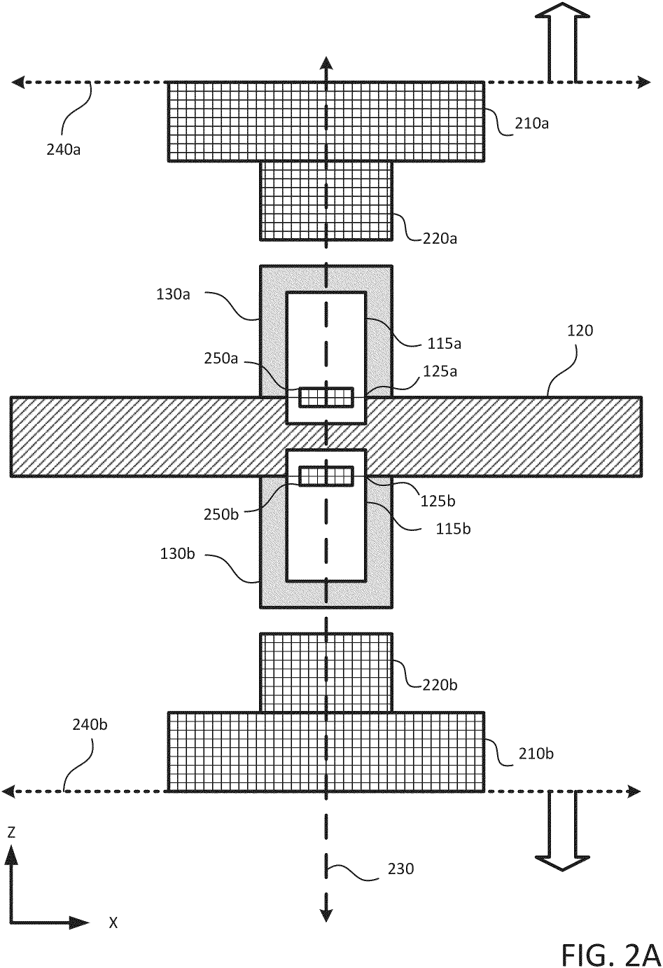

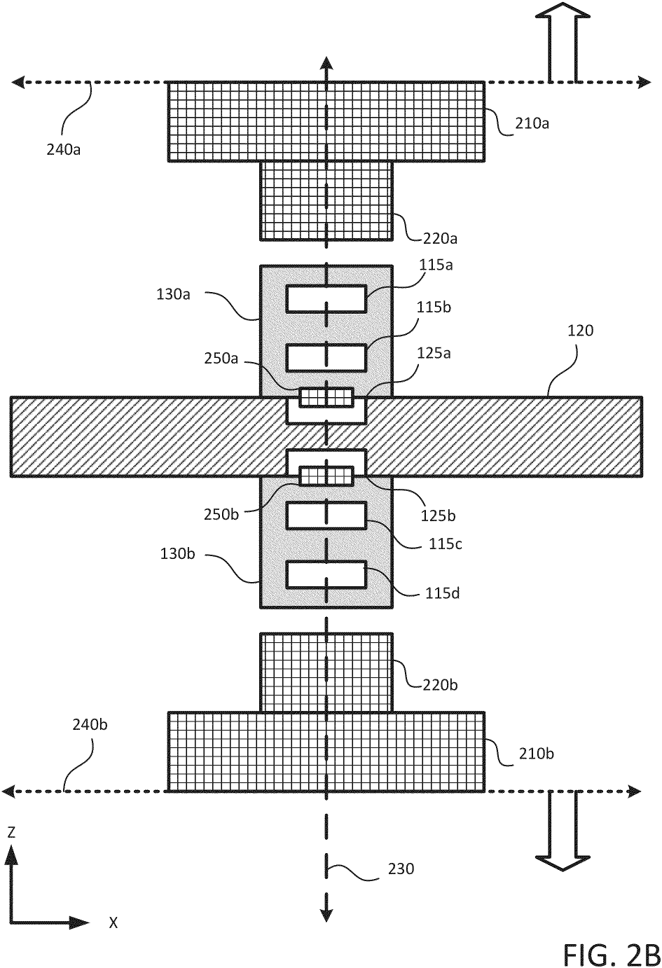

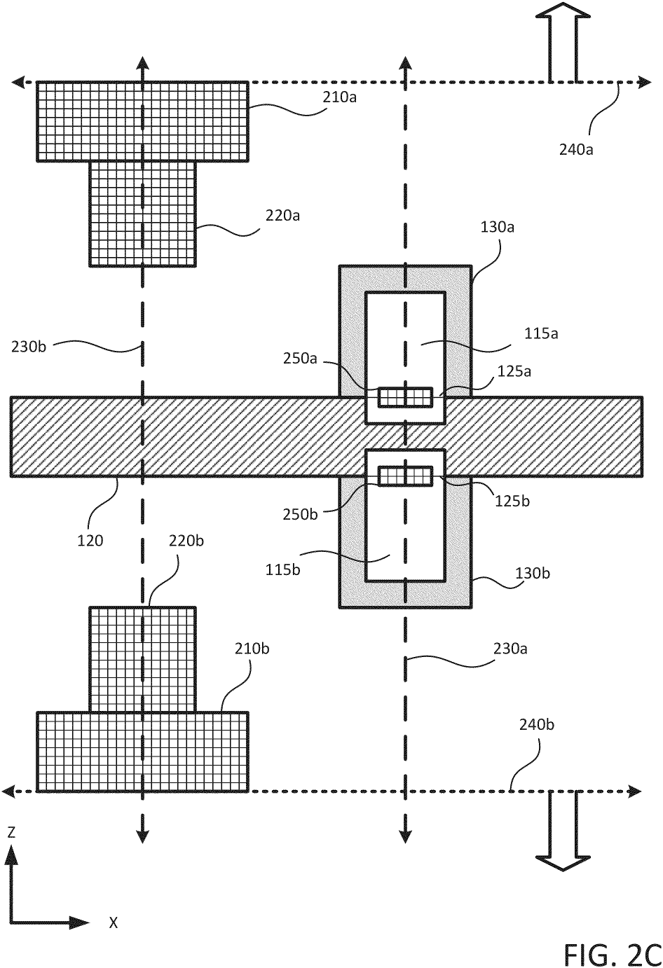

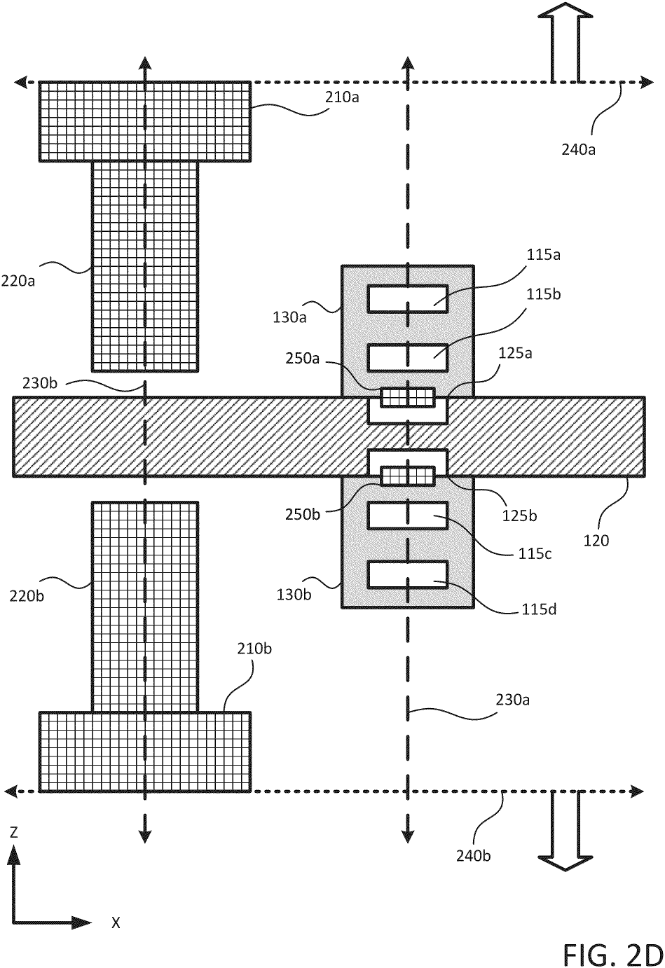

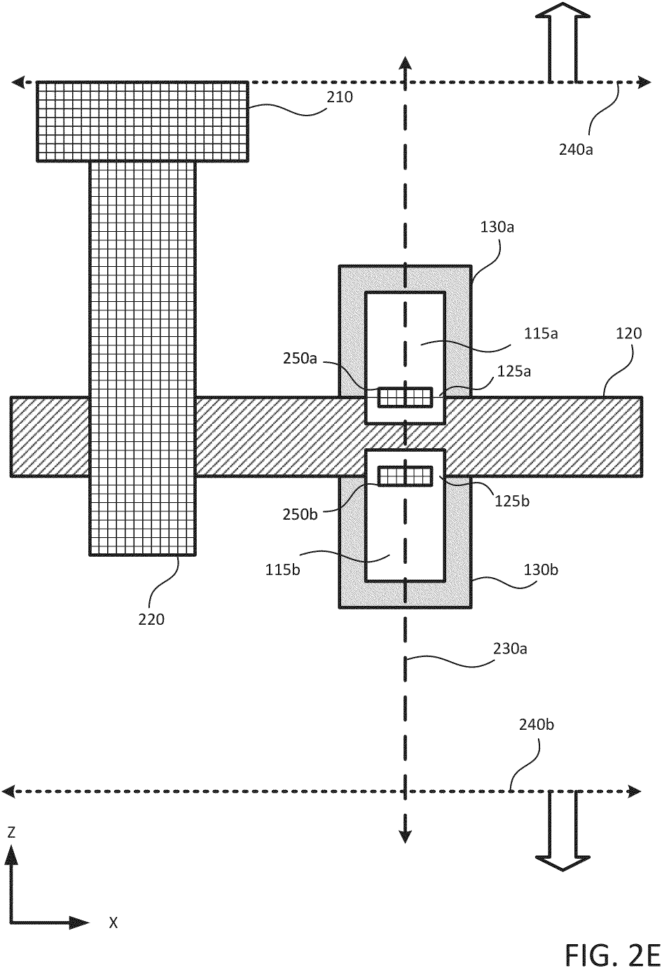

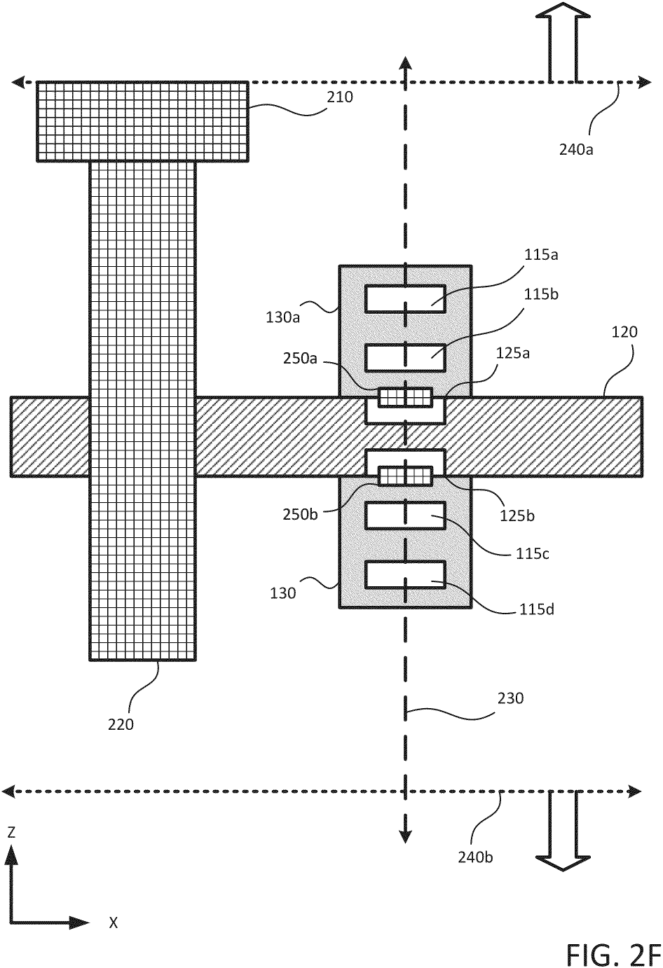

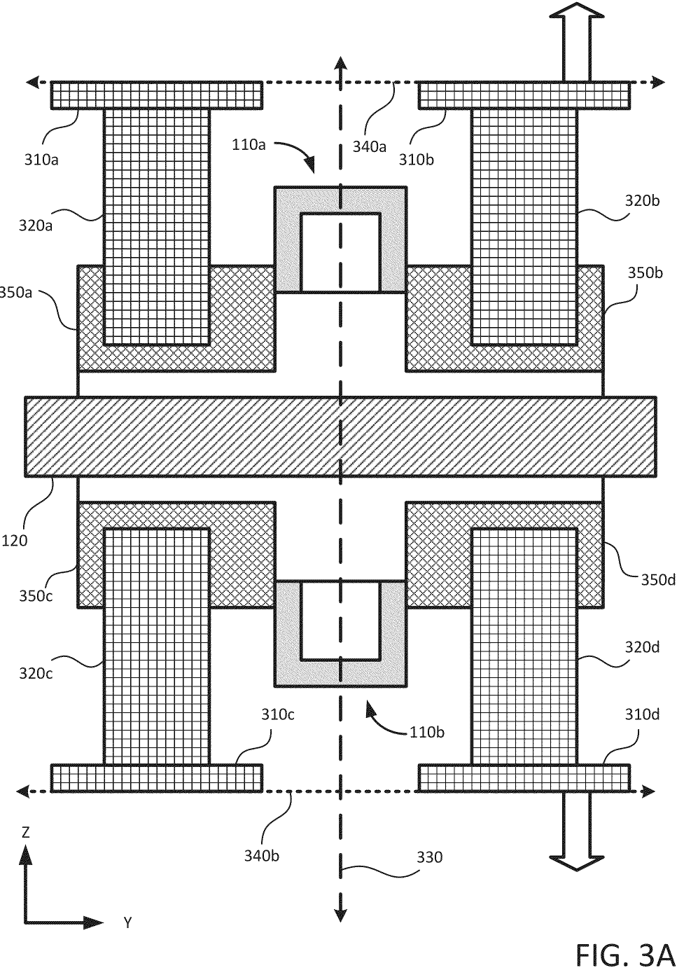

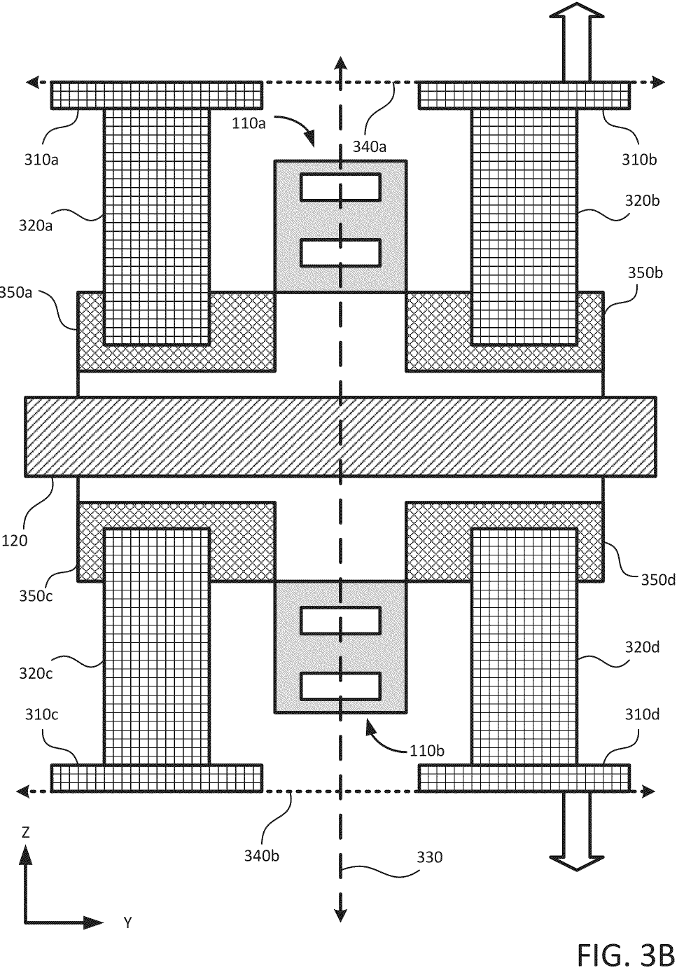

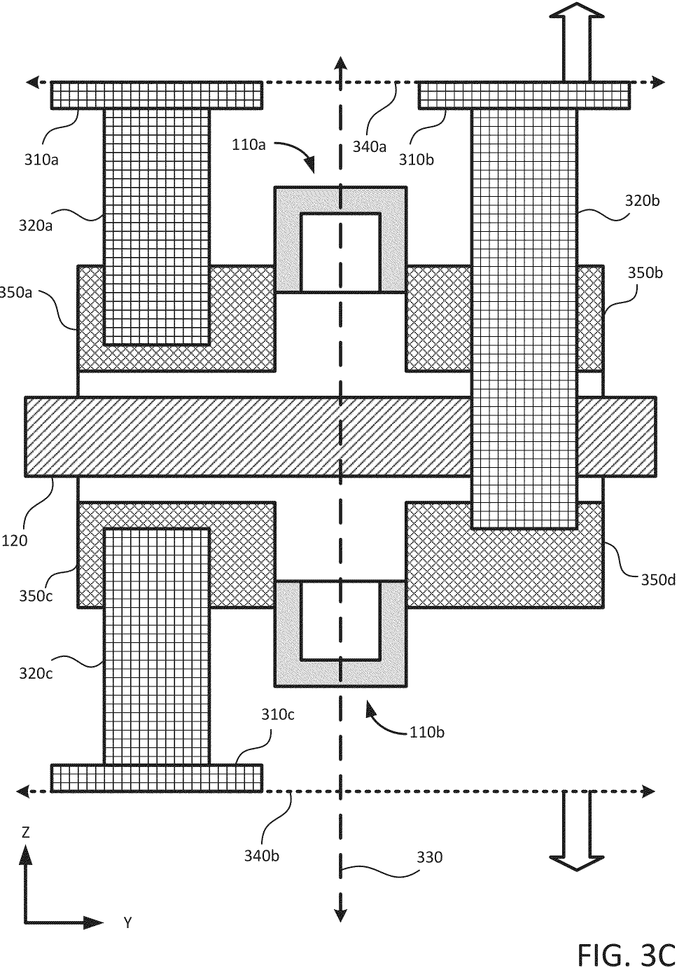

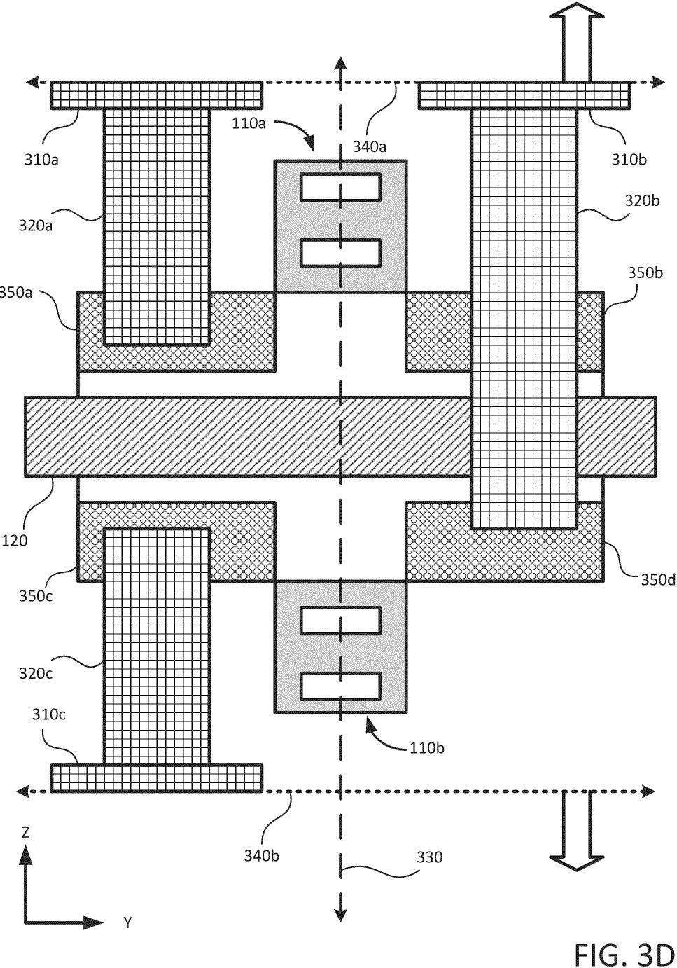

The channel regions 115, whether provided as a fin-type or a series of nanosheets, are made of a semiconductor (e.g., Silicon (Si), Germanium (Ge), SiGe, or the like) and are used to link a source to a drain through a gate structure that selectively permits (or blocks) the flow of current depending on whether a voltage is applied (or not applied) to the gate structure. In various embodiments, the channel regions 115 for each FET 110 are formed from or formed on a respective base layer 125a-b (generally or collectively, base layer 125) of a semiconductor. The base layer 125 may include power rails aligned with the channel regions 115. The power rails and contacts for the gate, drain, and source structures are described in greater detail in regard to FIGS. 2A-2C and 3A-3B.

In various embodiments, the FETs 110 located on opposite sides of the insulator 120 are doped for different operational characteristics. For example, the first FET 110a may be a p-type transistor, while the second FET 110b may be an n-type transistor, or vice versa.

In FIG. 1A, a first gate 130a (generally or collectively, gate 130) surrounds the channel region 115 of the first FET 110a on three sides, and a second gate 130b surrounds the channel region 115 of the second FET 110b on three sides. In FIG. 1B, the first gate 130a surrounds the channel regions 115a-c of the first FET 110a on four sides each, and a second gate 130b surrounds the channel regions 115d-f of the second FET 110b on four sides each. In various embodiments, the gates 130 are made of a metal or a polysilicon, silicide, Tungsten Nitride (WN), Tantalum Nitride (TaN), Titanium Nitride (TiN), Niobium, and may optionally include a high-k material such as Hafnium Dioxide (HfO₂) or Hafnium Oxynitride (HfON) with a high dielectric constant (k).

Shallow trench isolators (STI) 140a-d (generally or collectively STI 140) are included on each side of the channel regions 115. In various embodiments, the STI 140 are made of Silicon Dioxide (SiO₂) or a similar electrically insulating material. In various embodiments, the insulator 120 is made of the same or a different electrically insulating material from the STI 140. In various embodiments, the insulator 120 may be shared across several stacked FETs 110 so that a first pair of FETs 110 stacked on a first axis and a second pair of FETs stacked on a second axis, parallel to the first axis. Although not illustrated, the STI 140 may separate the FETs 110 from adjacent FETs 110 that are fabricated on the same die to project in the same direction from different locations (e.g., a third FET projecting in the same direction as the first FET 110a located at different XY coordinates), whereas the insulator 120 separates FETs 110 that are fabricated on the same die at the same location that project in different directions (e.g., the first FET 110a and the second FET 110b share the same XY coordinates

FIGS. 1A and 1B illustrate a fin plane 150 and a carrier plane 160 in which several cross-sectional views of the structure may be better understood. The fin plane 150 provides a cross-sectional view in the ZY plane that includes at least a portion of the gates 130 and any portions of the channel regions 115 included therein. The carrier plane 160 provides a cross-sectional view in the ZX plane that includes at least a portion of the gates 130 and at least a portion of the channel regions 115.

As will be appreciated, because some of the Figures depict in-process fabrication of the layouts 100, a given fin plane 150 or carrier plane 160 may include temporary elements that are not included in the final layout 100 or have shapes and size of elements that differ from those in the final layout 100. Similarly, various elements may be absent at various stages of fabrication, and are therefore absent in view that would otherwise include those elements in the given fin plane 150 or carrier plane 160 at a later time during fabrication. Additionally, although shown with various sizes, shapes, and quantities of components in the Figures, the elements are provided as non-limiting examples to illustrate potential embodiments of stacked FETs 110, which may include different sizes, shapes, and quantities of components from those illustrated in the Figures. Furthermore, various elements may be intentionally omitted or resized to better show certain relationships between the other elements.

FIGS. 2A-2F illustrate gate contact positions relative to a stacked pair of FETs, according to embodiments of the present disclosure. In each of the illustrated designs in FIGS. 2A-2F, various power rails 210a-b (generally or collectively, power rail 210) are shown in a carrier plane 160 in relation to a first and a second FET 110, which may be referred to as the top or bottom FET 110 relative to the insulator 120. In various embodiments, the power rails 210 are defined at the boundaries 240a-b of the cell including the stacked FETs 110, but in other embodiments, the boundaries 240a-b may be located further away (e.g., in the Z direction) from power rails 210 that are internal to the cell. Return rails 250a-b (generally or collectively, return rail 250) may be included in or on the respective base layer 125 to complete a circuit with the illustrated power rails 210.

FIG. 2A illustrates a fully-stacked FINFET design that includes a top contact 220a (generally or collectively, contact 220) connected to a first power rail 210a for controlling the top gate 130a of a top FET 110a. Additionally, FIG. 2A illustrates a bottom contact 220b connected to a second power rail 210b for controlling the bottom gate 130b of a bottom FET 110b. The top FET 110a and the bottom FET 110b are separated from each other by an insulator 120. However, in FIG. 2A, the first power rail 210a, the top contact 220a, the top gate 130a, the top FET 110a, the insulator 120, the bottom FET 110b, the bottom gate 130b, the bottom contact 220b, and the second power rail 210b are stacked along an axis 230 (e.g., in the Z direction).

FIG. 2B illustrates a fully-stacked nanosheet design that includes a top contact 220a connected to a first power rail 210a for controlling the top gate 130a of a top FET 110a. Additionally, FIG. 2B illustrates a bottom contact 220b connected to a second power rail 210b for controlling the bottom gate 130b of a bottom FET 110b. The top FET 110a and the bottom FET 110b are separated from each other by an insulator 120. However, in FIG. 2A, the first power rail 210a, the top contact 220a, the top gate 130a, the top FET 110a, the insulator 120, the bottom FET 110b, the bottom gate 130b, the bottom contact 220b, and the second power rail 210b are stacked along an axis 230 (e.g., in the Z direction).

FIG. 2C illustrates a rail-offset design for stacked FINFETs that includes a top contact 220a connected to a first power rail 210a for controlling the top gate 130a of a top FET 110a. Additionally, FIG. 2C illustrates a bottom contact 220b connected to a second power rail 210b for controlling the bottom gate 130b of a bottom FET 110b. The top FET 110a and the bottom FET 110b are separated from each other by an insulator 120. In FIG. 2B, the first power rail 210a, the top contact 220a, the bottom contact 220b, and the second power rail 210b are aligned on a first axis 230a while the top FET 110a, the insulator 120, and the bottom FET 110b are stacked along a second axis 230b parallel to the first axis 230a.

FIG. 2D illustrates a rail-offset design for stacked nanosheets that includes a top contact 220a connected to a first power rail 210a for controlling the top gate 130a of a top FET 110a. Additionally, FIG. 2D illustrates a bottom contact 220b connected to a second power rail 210b for controlling the bottom gate 130b of a bottom FET 110b. The top FET 110a and the bottom FET 110b are separated from each other by an insulator 120. In FIG. 2C, the first power rail 210a, the top contact 220a, the bottom contact 220b, and the second power rail 210b are aligned on a first axis 230a while the top FET 110a (including the top gate 130a and channel regions 115a-c), the insulator 120, and the bottom FET 110b (including the bottom gate 130b and channel regions 115d-f) are stacked along a second axis 230b parallel to the first axis 230a.

FIG. 2D illustrates a shared rail design for stacked FINFETs that includes a top contact 220a connected to a first power rail 210a for controlling the top gate 130a of a top FET 110a and the bottom gate 130b of a bottom FET 110b. The top FET 110a and the bottom FET 110b are separated from each other by an insulator 120. In FIG. 2D, the first power rail 210a and top contact 220a, the bottom contact 220b are disposed off the shared axis 230 that the top FET 110a, the insulator 120, and the bottom FET 110b are stacked along.

FIG. 2E illustrates a shared rail design for stacked nanosheets that includes a top contact 220a connected to a first power rail 210a for controlling the top gate 130a of a top FET 110a and the bottom gate 130b of a bottom FET 110b. The top FET 110a and the bottom FET 110b are separated from each other by an insulator 120. In FIG. 2E, the first power rail 210a and top contact 220a, the bottom contact 220b are disposed off the shared axis 230 that the top FET 110a (including the top gate 130a and channel regions 115a-c), the insulator 120, and the bottom FET 110b including the bottom gate 130b and channel regions 115d-f) are stacked along.

In each of the designs shown in FIGS. 2A-2D, each of the FETS 110 are connected to a power rail 210 with the same resistance as one another and that avoids the extra physical space required for mounting power rails 210 on the same side of the cell containing the FETS 110. Accordingly, the designs each provide for greater control and regularity in the FETS 110 and for smaller footprints in the overall design, among other benefits.

FIGS. 3A-3D illustrate source and drain contact positions relative to a stacked pair of FETs, according to embodiments of the present disclosure. Each of the illustrated designs in FIGS. 3A-3D are shown in a fin plane 150, with various rails 310a-d (generally or collectively, rail 310) shown in relation to the source or drain regions 350a-d (generally or collectively, source/drain regions 350) a first and a second FET 110, which may be referred to as the top or bottom FET 110 relative to the insulator 120. In various embodiments, the rails 310 are defined at the boundaries 340a-b of the cell including the stacked FETs 110, but in other embodiments, the boundaries 340a-b may be located further away (e.g., in the Z direction) from rails 310 that are internal to the cell. In various embodiments, the rails 310 for the sources and drains may be set at a same height or a different height than the power rails 210 for the gates (shown in FIGS. 2A-2E). In various embodiments, the layouts shown in FIGS. 2A, 2C, and 2E may be combined with either of FIGS. 3A and 3C. Similarly, the layouts shown in FIGS. 2B, 2D, and 2F may be combined with either of FIGS. 3B and 3D in various embodiments.

FIG. 3A illustrates an individual design for stacked FINFETs that includes a first contact 320a (generally or collectively, contact 320) connected to a first rail 310a for electrically connecting a first source/drain region 350a of the top FET 110a, and a second contact 320b connected to a second rail 310b for electrically connecting a second source/drain region 350b of the top FET 110a. Additionally, FIG. 3A illustrates a third contact 320c connected to a third rail 310c electrically connecting a third source/drain region 350c of the bottom FET 110b, and a fourth contact 320d connected to a fourth rail 310d electrically connecting a fourth source/drain region 350d of the bottom FET 110b. The top FET 110a and the bottom FET 110b are separated from each other by an insulator 120. In FIG. 3A, the top FET 110a, the insulator 120, and the bottom FET 110b are stacked along an axis 330, but the rails 310 and contacts 320 may be aligned off axis from the gates of the FETs 110 in one or more planes according to various trace routing considerations.

FIG. 3B illustrates an individual design for stacked nanosheets that includes a first contact 320a connected to a first rail 310a for electrically connecting a first source/drain region 350a of the top FET 110a, and a second contact 320b connected to a second rail 310b for electrically connecting a second source/drain region 350b of the top FET 110a. Additionally, FIG. 3B illustrates a third contact 320c connected to a third rail 310c electrically connecting a third source/drain region 350c of the bottom FET 110b, and a fourth contact 320d connected to a fourth rail 310d electrically connecting a fourth source/drain region 350d of the bottom FET 110b. The top FET 110a (including the top gate 130a and channel regions 115a-b) and the bottom FET 110b (including the bottom gate 130b and channel regions 115c-d) are separated from each other by an insulator 120. In FIG. 3A, the top FET 110a, the insulator 120, and the bottom FET 110b are stacked along an axis 330, but the rails 310 and contacts 320 may be aligned off axis from the gates of the FETs 110 according to various trace routing considerations.

FIG. 3C illustrates a shared design for stacked FINFETs that includes a first contact 320a connected to a first rail 310a for electrically connecting a first source/drain region 350a of the top FET 110a, and a third contact 320c for electrically connecting a third source/drain region 350c of the bottom FET 110b. A second contact 320b is shared by the top FET 110a and the bottom FET 110b to connect to a second rail 310b for electrically connecting the remaining second source/drain region 350b and 350d for both FETs 110. The top FET 110a and the bottom FET 110b are separated from each other by an insulator 120. In FIG. 3C, the top FET 110a, the insulator 120, and the bottom FET 110b are stacked along an axis 330, but the rails 310 and contacts 320 may be aligned off axis from the gates of the FETs 110 in one or more planes according to various trace routing considerations.

FIG. 3D illustrates a shared design for stacked nanosheets that includes a first contact 320a connected to a first rail 310a for electrically connecting a first source/drain region 350a of the top FET 110a, and a third contact 320c for electrically connecting a third source/drain region 350c of the bottom FET 110b. A second contact 320b is shared by the top FET 110a and the bottom FET 110b to connect to a second rail 310b for electrically connecting the remaining second source/drain region 350b and 350d for both FETs 110. The top FET 110a and the bottom FET 110b are separated from each other by an insulator 120. In FIG. 3D, the top FET 110a, the insulator 120, and the bottom FET 110b are stacked along an axis 330, but the rails 310 and contacts 320 may be aligned off axis from the gates of the FETs 110 in one or more planes according to various trace routing considerations.

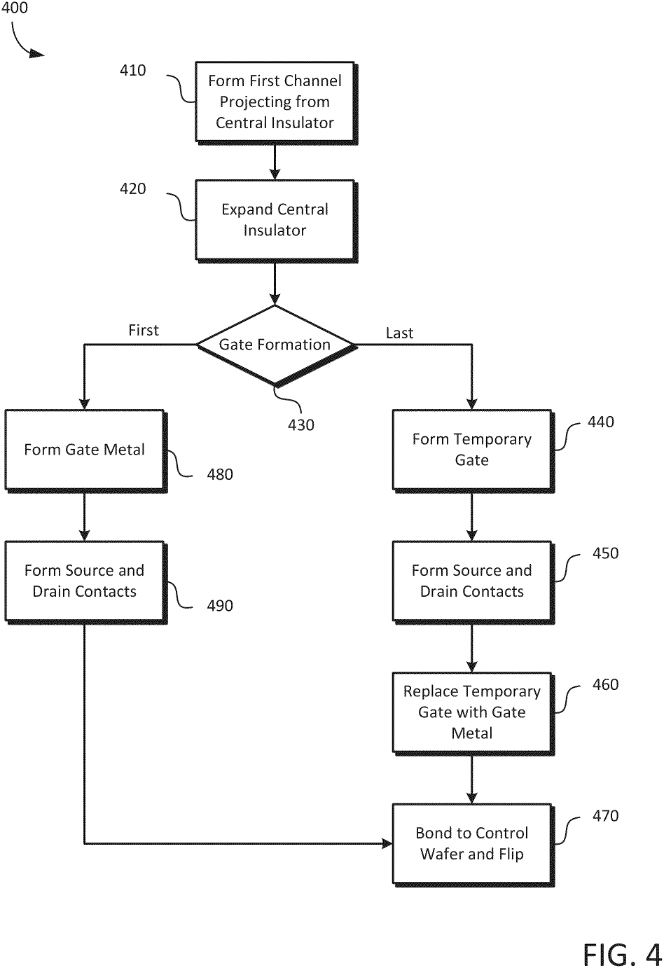

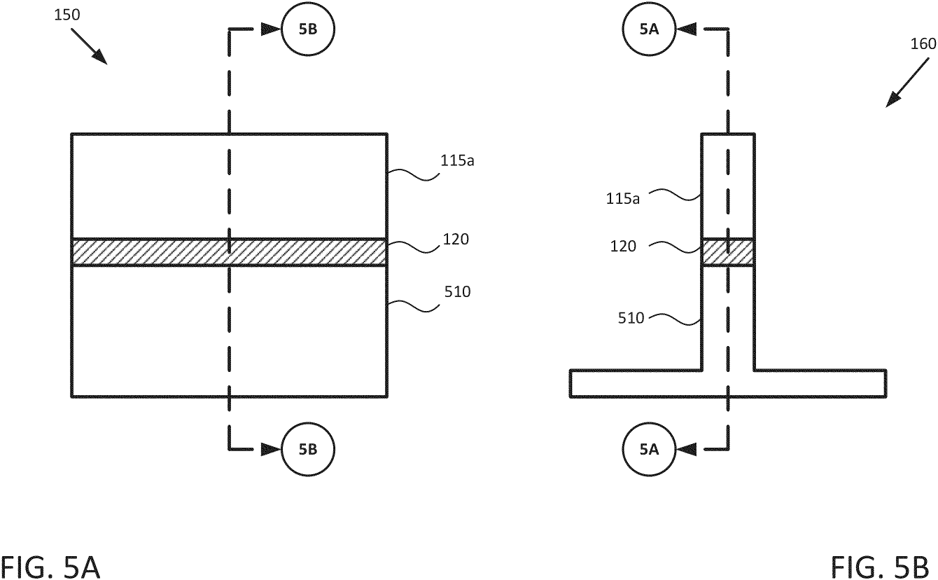

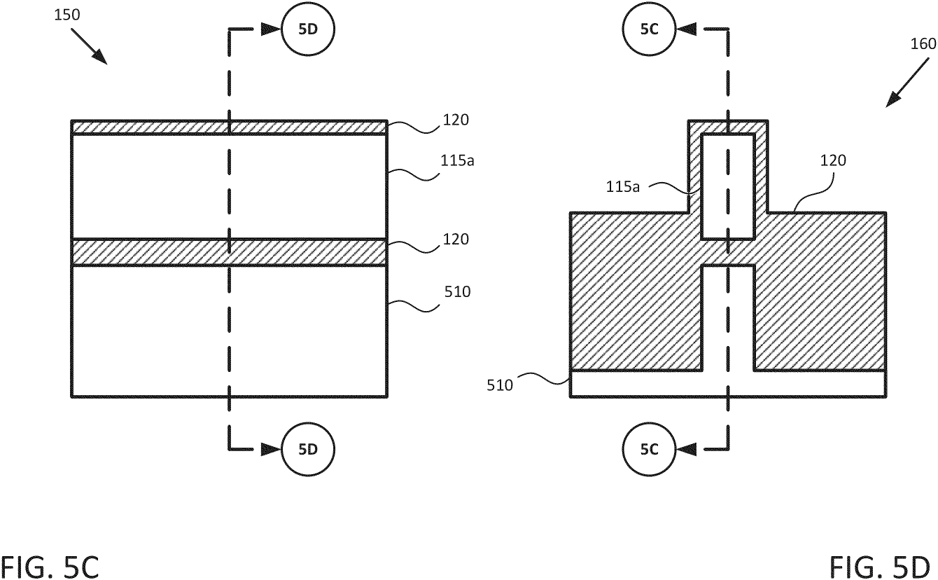

FIG. 4 is a flowchart of a method 400 for front-side fabrication of a first FET 1 10a in a stacked layout, according to embodiments of the present disclosure. Method 400 may be understood in conjunction with FIGS. 5A-5D, 6A-6J, and 7A-7H which illustrate several views of the structure during fabrication, according to embodiments of the present disclosure. Although FIGS. 5A-5D, 6A-6J, and 7A-7H illustrate the transistors being fabricated as FinFET transistors, it will be appreciated that method 400 may also be applied in constructing nanosheet transistors.

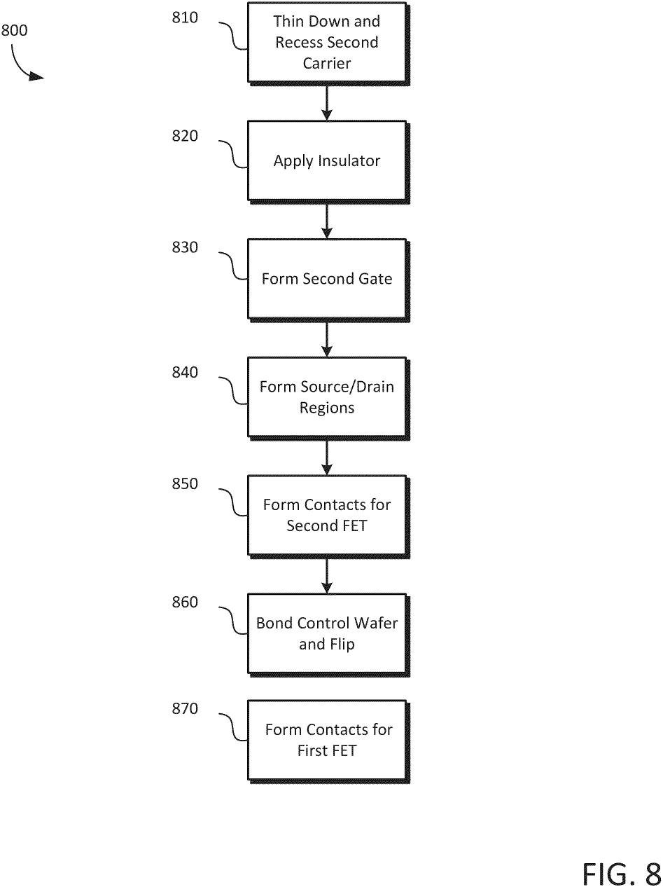

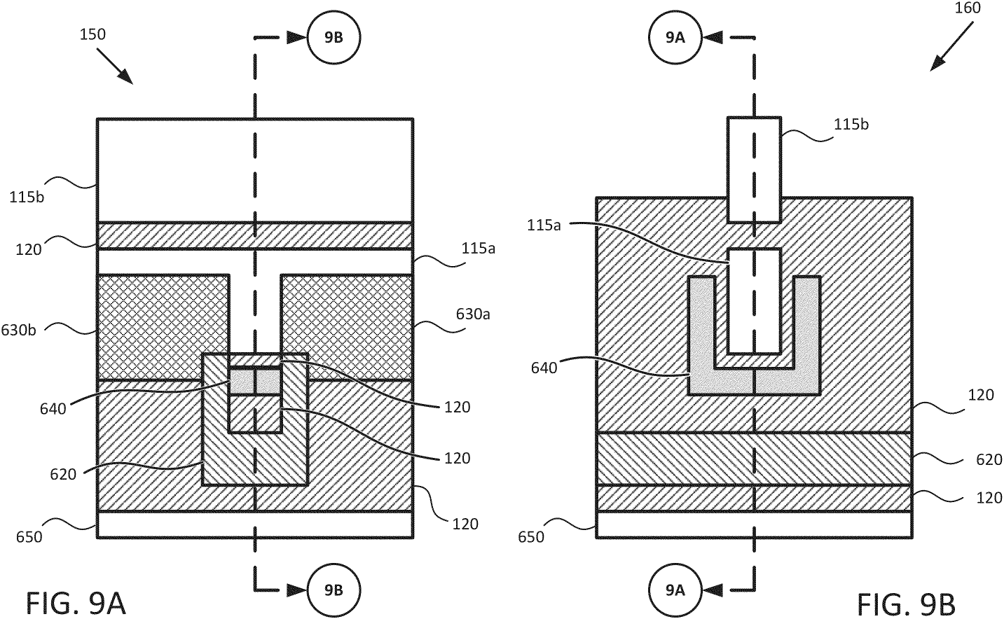

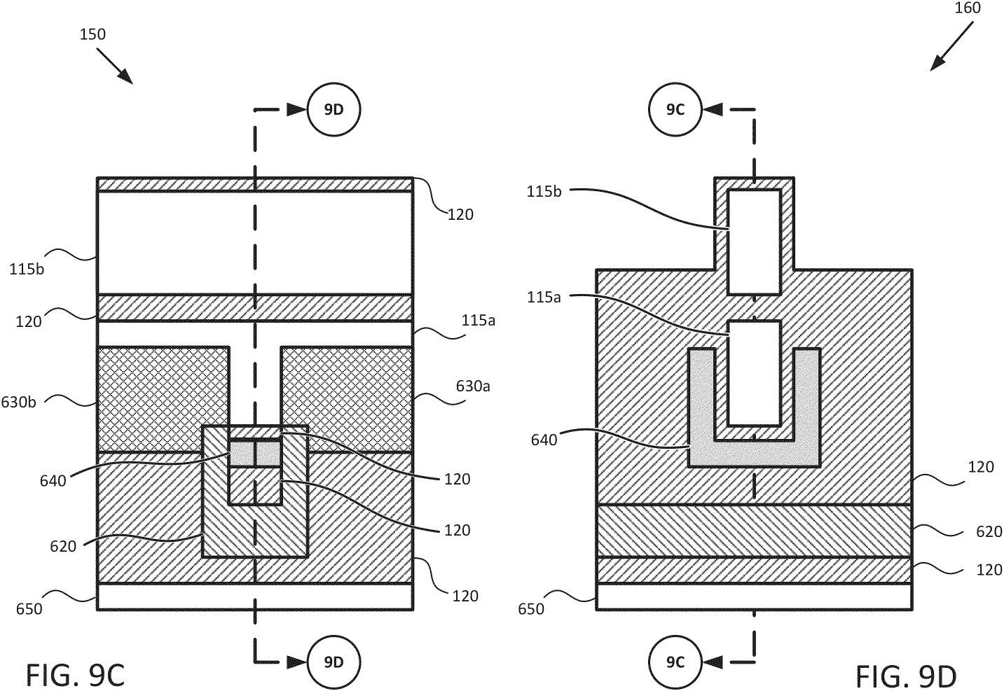

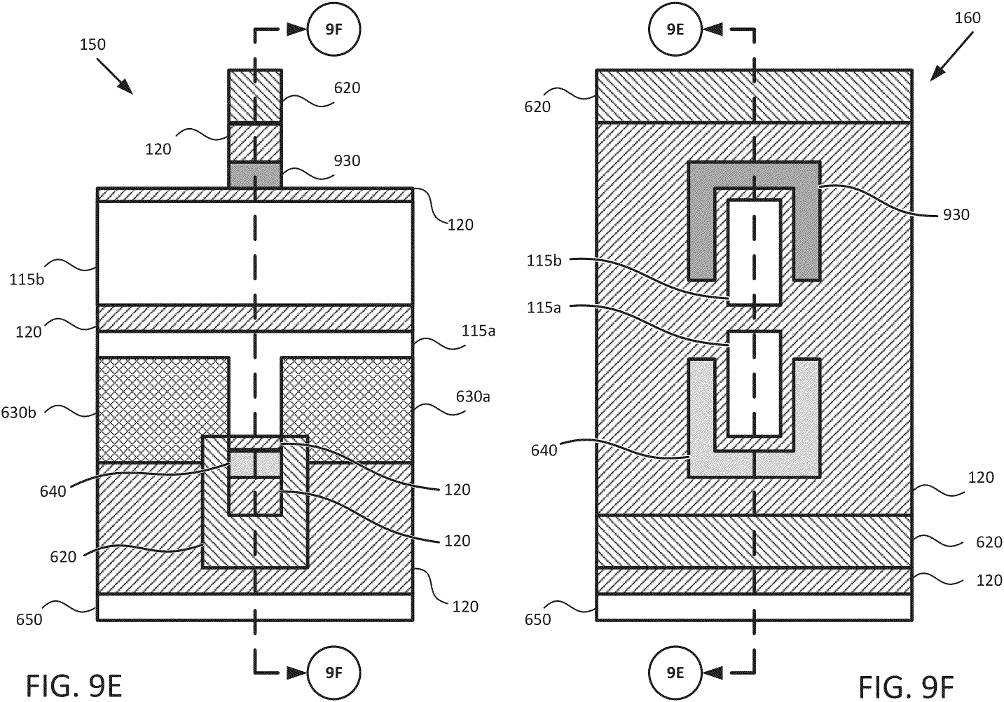

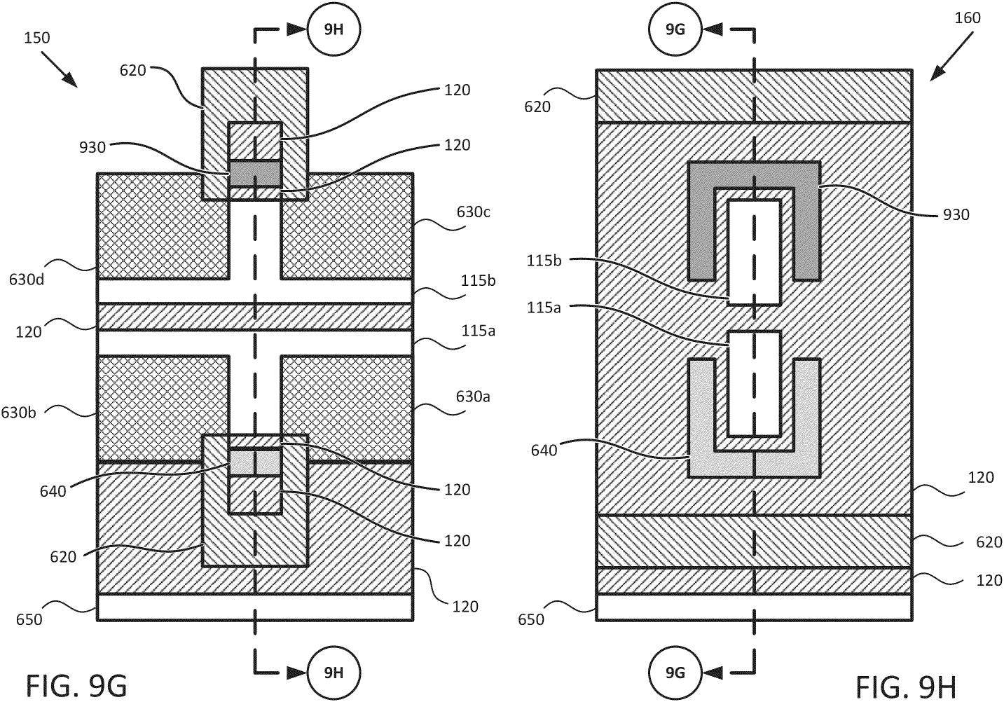

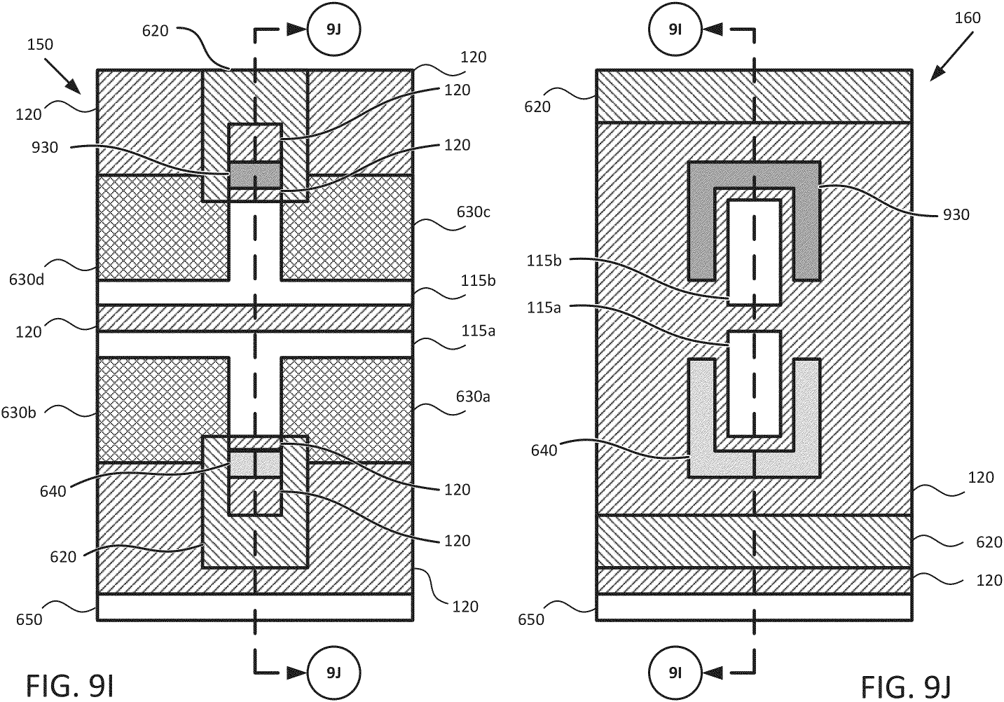

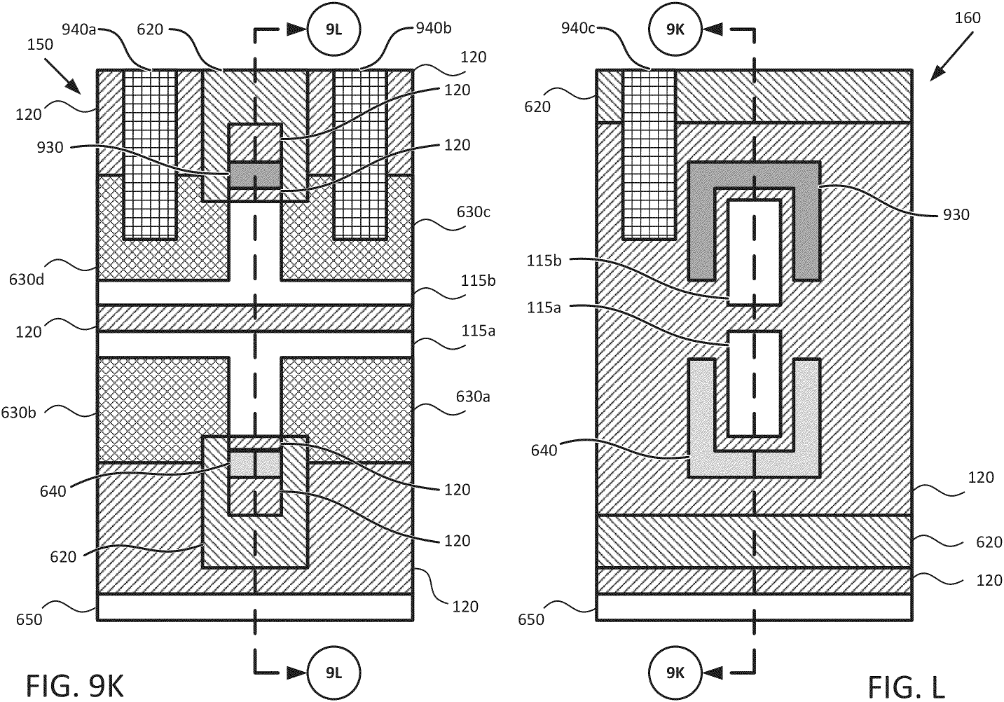

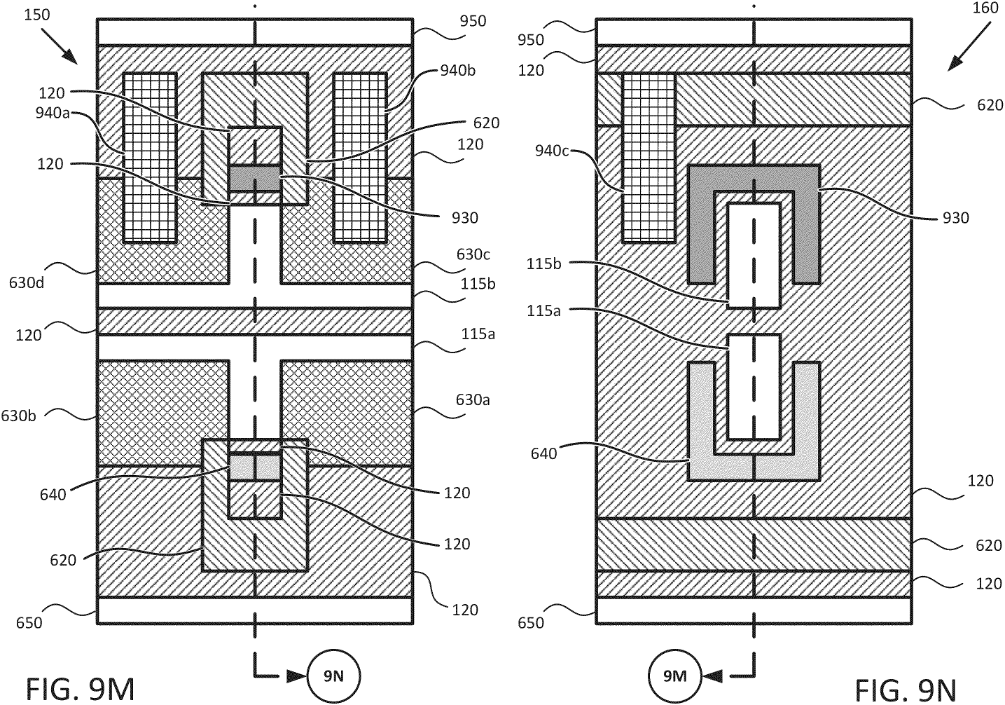

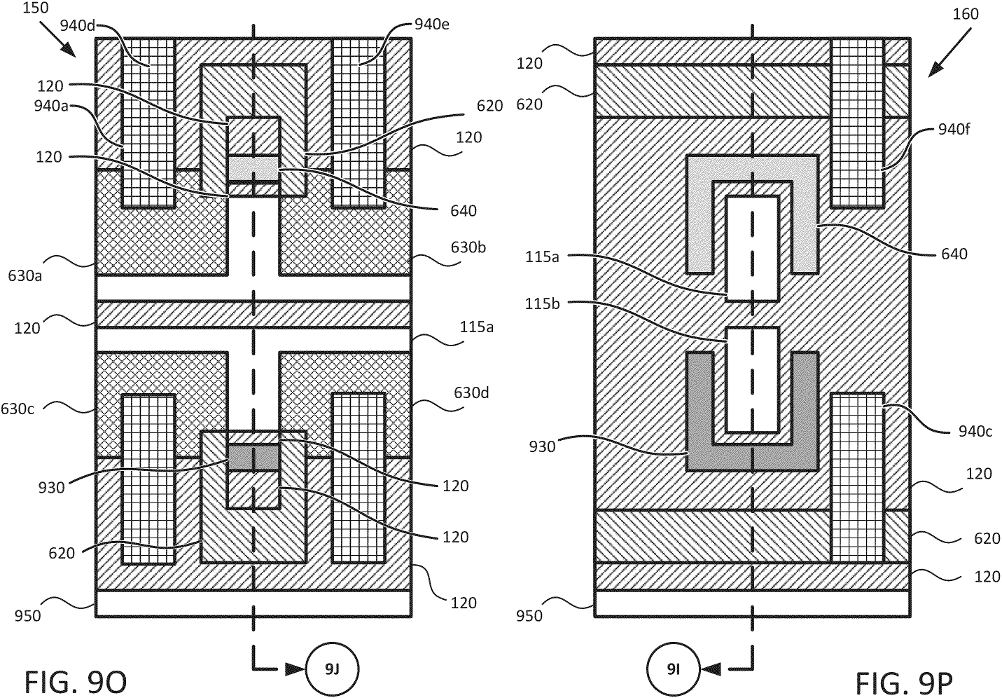

Method 400 begins at block 410, where a fabricator forms a first channel region 115a for the first FET 110a that projects from a central insulator 120 for a stacked FET layout 100. The fabricator defines a semiconductor on insulator structure that includes the insulator 120, the first channel regions 115a, and a base layer 510 of silicon (or other semiconductor) such as those shown in FIG. 5A in a fin plane 150 and in FIG. 5B in a carrier plane 160. The base layer 510 will form the basis for the second channel regions 115b after the first FET 110a is formed, as is discussed in greater detail in regard to FIGS. 8 and 9A-9P.

At block 420, the fabricator expands the central insulator 120 around the first channel regions 115a and the portions of the base layer 510 that will become the second channel regions 115b, such as that shown in FIG. 5C in a fin plane 150 and in FIG. 5D in a carrier plane 160.

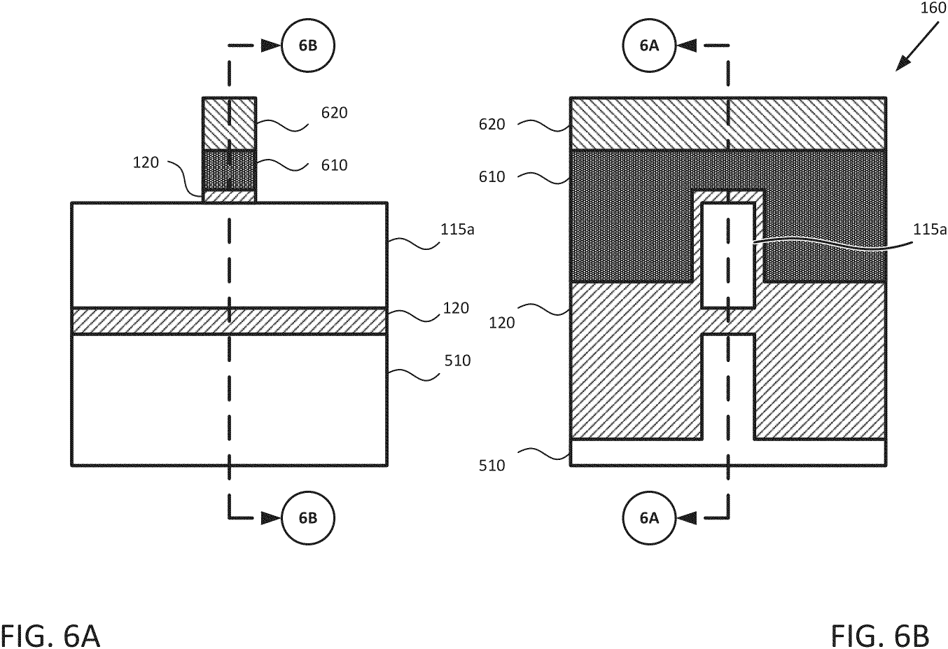

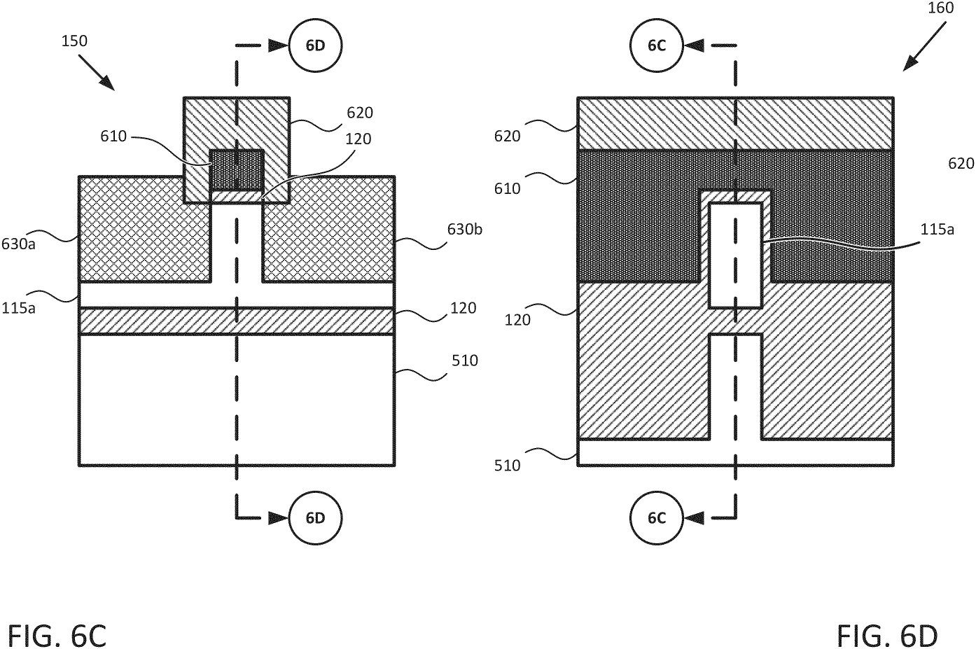

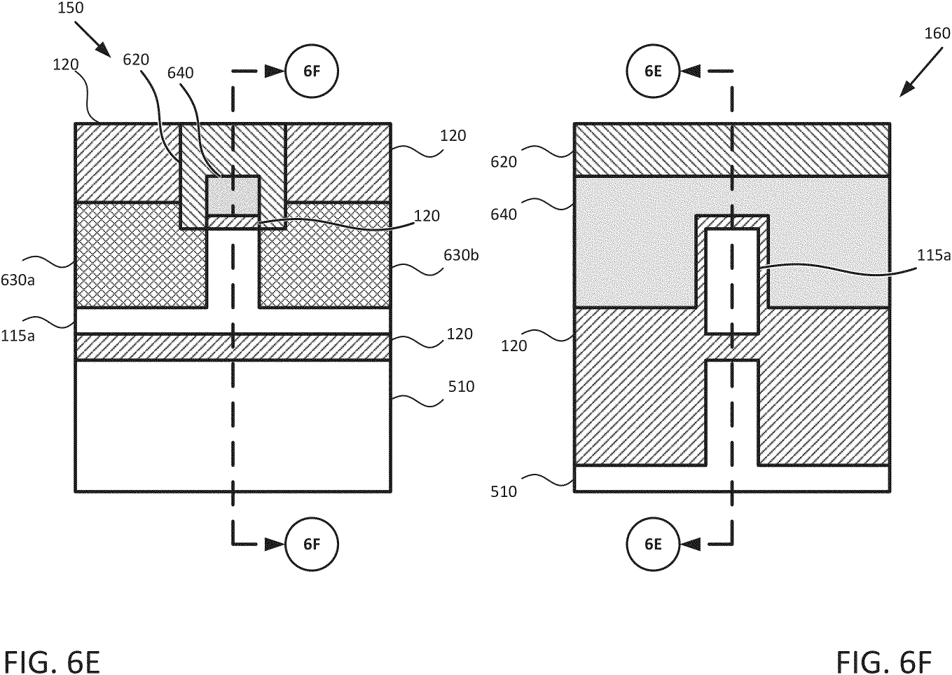

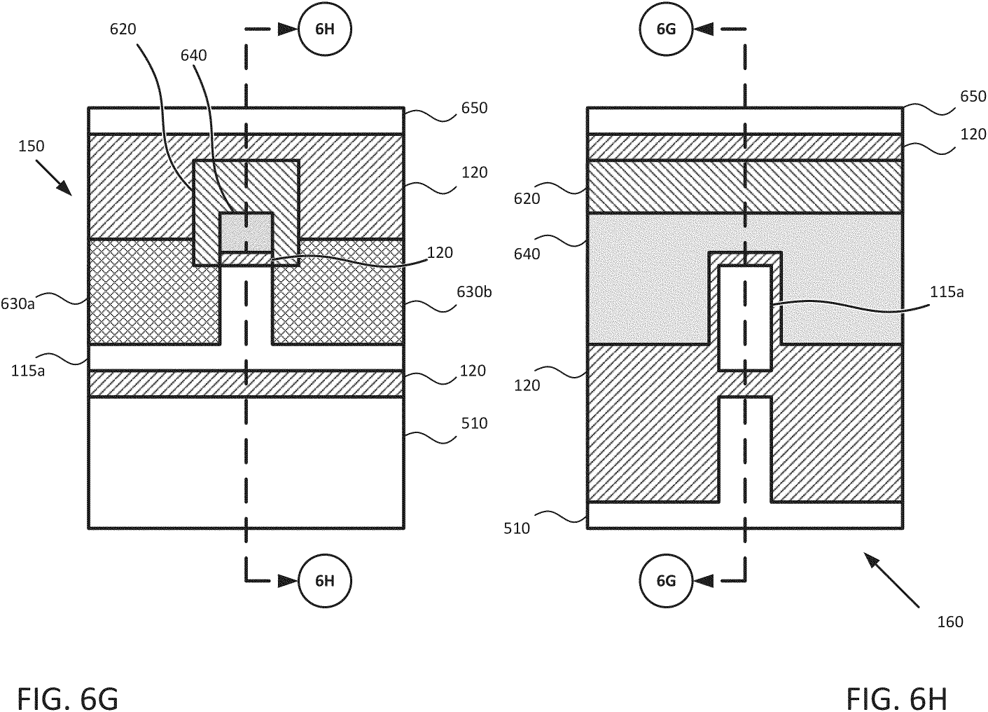

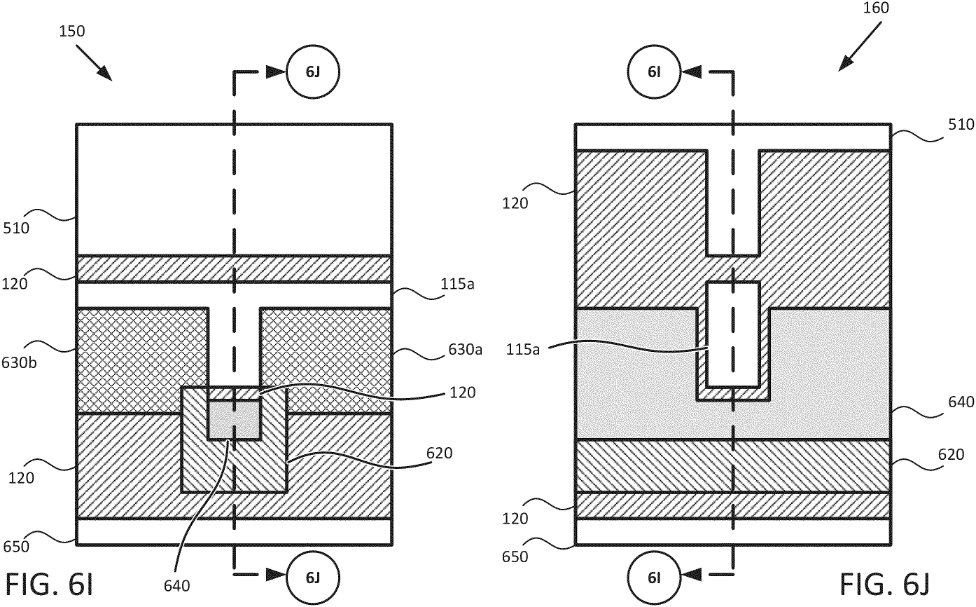

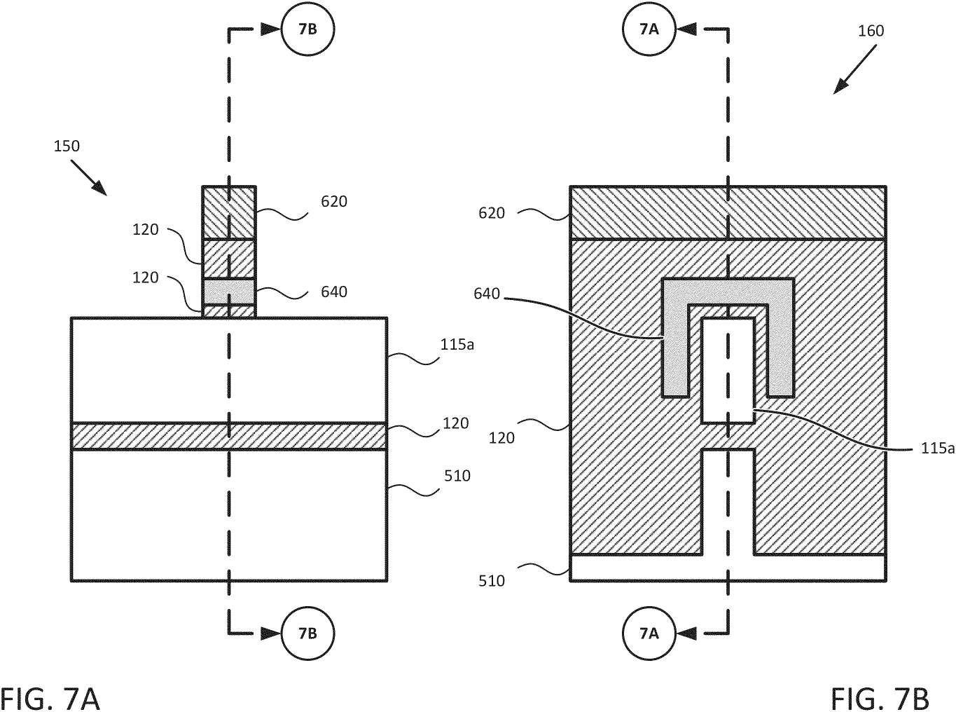

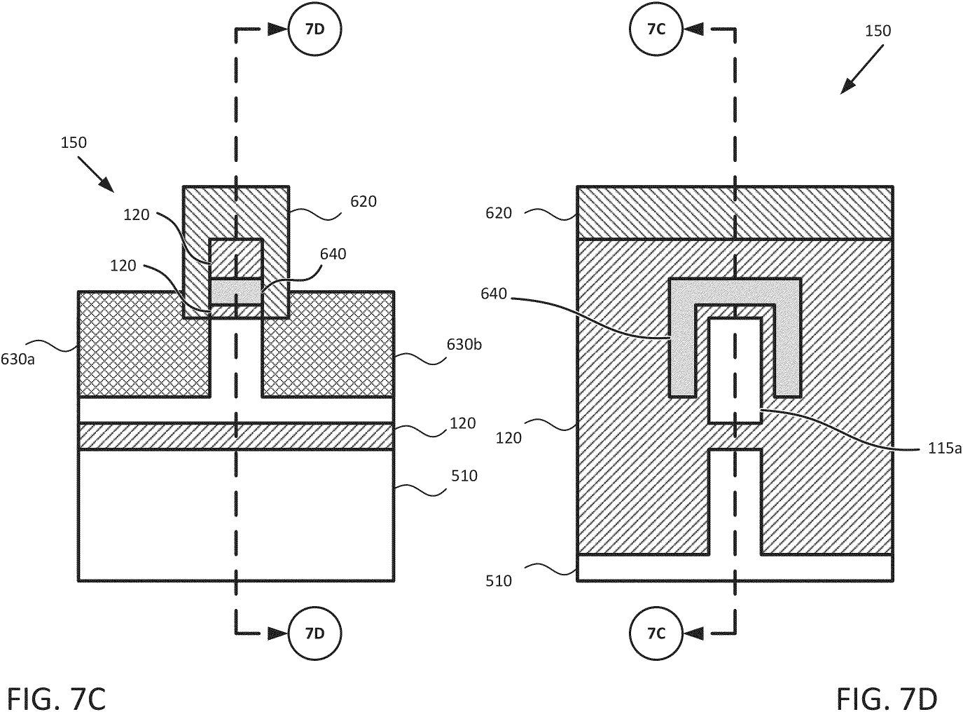

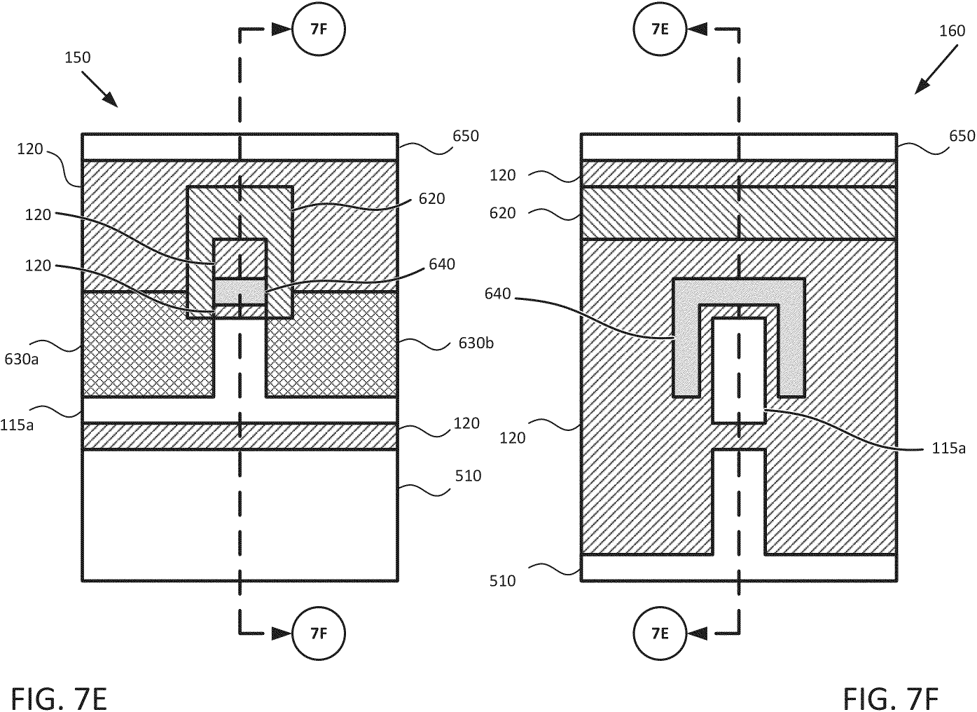

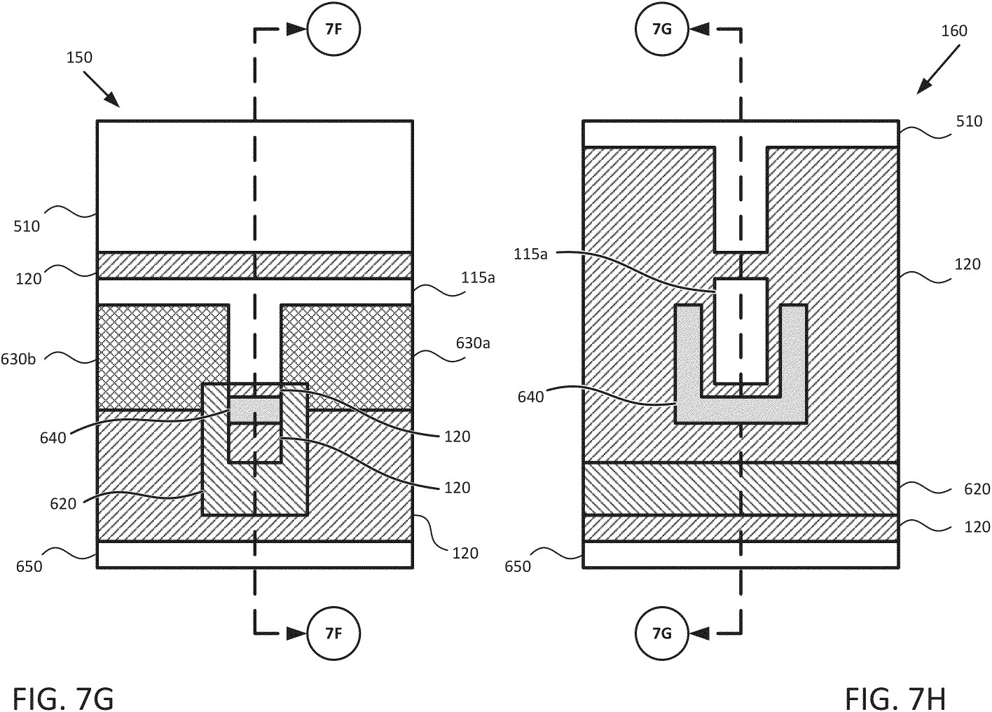

Method 400 proceeds from block 430 to block 440 when the fabricator determines to perform gate formation last, and to block 480 when the fabricator determines to perform gat fabrication first. Blocks 440-470 may be understood in relation to FIGS. 6A-6J. Blocks 480-490 and 470 may be understood in relation to FIGS. 7A-7H.

At block 440 the fabricator forms a temporary gate 610, such as that shown in FIG. 6A in a fin plane 150 and in FIG. 6B in a carrier plane 160. The temporary gate 610 may be made of Si or another material to temporarily hold components of the FET 110 in place during fabrication and to allow the deposition of other components before the actual gate metals are deposited. For example, the fabricator may form a top layer of an encapsulation material 620 (e.g., Silicon Nitride (SiN)) on top of the temporary gate material, as is shown in FIGS. 6A and 6B.

At block 450, the fabricator forms the source/drain regions 630a-b (generally or collectively, source/drain regions 630) for the source and the drain for the first FET 110a, such as that shown in FIG. 6C in a fin plane 150 and in FIG. 6D in a carrier plane 160. The fabricator removes (e.g., via a chemical/mechanical etching process) a portion of the first channel region 115a where the source/drain regions 630 are to be formed, and may form additional layers of the encapsulation material 620 to conform around the temporary gate 610 on at least three sides.

At block 460, the fabricator replaces the temporary gate 610 with the gate 640, such as that shown in FIG. 6E in a fin plane 150 and in FIG. 6F in a carrier plane 160. In various embodiments, the gate 640 is made of a metal or a polysilicon, silicide, WN, TaN, TiN, Niobium, and may optionally include a high-k material such as HfO₂ or HfON with a high dielectric constant (k) as an inner layer relative to the channel region 115. The fabricator may remove the temporary gate 610 via a chemical/mechanical etching process, and form the gate 640 via vapor deposition in various embodiments. Once the gate 640 is formed, the fabricator may apply additional insulator 120 above the gate 640 and planarize the newly added insulator 120 with the upper surface of the encapsulation material 620.

At block 470, the fabricator bonds the structure to a control wafer 650 and flips the structure in preparation for forming the second FET 110b. In various embodiments, the fabricator may apply additional layers of the insulator 120 and planarize the newly added insulator 120 with the upper surface of the encapsulation material 620. A control wafer 650, which may include a Si wafer including various electrical traces or physical contact features to help the fabricator move the die including the stack FET cells during production, bonds to the uppermost layer of the insulator 120 to produce the structure seen a fin plane 150 of FIGS. 6G or 7E and in a carrier plane 160 of FIGS. 6H or 7F.

FIGS. 6I and 6J illustrate flipped versions of the first FET 110a as shown in FIGS. 6G and 6H, respectively, to prepare for fabrication of the second FET 110b. Similarly, FIGS. 7G and 7H illustrate flipped versions of the first FET 110a as shown in FIGS. 7E and 7F, respectively, to prepare for fabrication of the second FET 110b.

At block 480, the fabricator forms a gate 640, such as that shown in FIG. 7A in a fin plane 150 and in FIG. 7B in a carrier plane 160. In various embodiments, the gate 640 is made of a metal or a polysilicon, silicide, WN, TaN, TiN, Niobium, and may optionally include a high-k material such as HfO₂ or HfON with a high dielectric constant (k) as an inner layer relative to the channel region 115. A layer of the insulator 120 separates the gate 640 from the channel region 115, and the fabricator defines an additional layer of the insulator 120 above the gate 640, on which a top layer of encapsulation material 620 (e.g., SiN) is formed.

At block 490, the fabricator forms the source/drain regions 630a-b for the source and the drain for the first FET 110a, such as that shown in FIG. 7C in a fin plane 150 and in FIG. 7D in a carrier plane 160. The fabricator removes (e.g., via a chemical/mechanical etching process) a portion of the first channel region 115a where the source/drain regions 630 are to be formed, and may form additional layers of the encapsulation material 620 to conform around the gate 640, the first channel region 115a, and the intermediary insulator 120 on at least three sides.

FIG. 8 is a flowchart of a method 800 for back-side fabrication of a second FET 110b in a stacked layout, according to embodiments of the present disclosure. Method 800 may be understood as a continuation of method 400 discussed in relation to FIG. 4 and in conjunction with FIGS. 9A-9P, which illustrate several views of the structure during fabrication, according to embodiments of the present disclosure.

Although FIGS. 9A-9P illustrate the transistors being fabricated as FinFET transistors, it will be appreciated that method 800 may also be applied in constructing nanosheet transistors, where both method 800 and method 800 fabricate the associated FETs 110 to be FinFET or nanosheet type transistors. Similarly, although FIGS. 9A-9P illustrate the first FET 110a according to the embodiments shown in FIGS. 7A-7H, the fabricator may continue the process illustrated in FIGS. 6A-6J. Moreover, although method 800 discusses and FIGS. 9A-9P illustrate a gate-first process (e.g., similar to that described in blocks 470-490 of method 400 in relation to FIGS. 4 and 7A-7H), the present disclosure also envisions that the fabricator may perform method 800 via a gate-last process (e.g. similar to that described in blocks 440-470 of method 400 in relation to FIGS. 4 and 6A-6J).

Method 800 begins a block 810, where the fabricator thins down the base layer 510 (as shown in FIGS. 7G and 7H) and recesses the insulator 120 to produce and expose the second channel region 115b, such as that shown in FIG. 9A in a fin plane 150 and in FIG. 9B in a carrier plane 160.

At block 820, the fabricator applies an additional layer of the insulator 120 over the second channel region 115, such as that shown in FIG. 9C in a fin plane 150 and in FIG. 9D in a carrier plane 160.. In various embodiments, the fabricator may in addition to or instead of the additional layer of insulator 120 apply a layer of a high-k material over the second channel region 115b.

At block 830, the fabricator forms the second gate 910, such as that shown in FIG. 9E in a fin plane 150 and in FIG. 9F in a carrier plane 160. In various embodiments, the gate 640 is made of a metal or a polysilicon, silicide, WN, TaN, TiN, Niobium, and may optionally include a high-k material such as HfO₂ or HfON with a high dielectric constant (k) as an inner layer relative to the channel region 115. A layer of the insulator 120 separates the gate 640 from the channel region 115, and the fabricator defines an additional layer of the insulator 120 above the gate 930, on which a second layer of encapsulation material 620 (e.g., SiN) is formed.

At block 840, the fabricator forms the source/drain regions 630c-d for the source and the drain for the second FET 110b, such as that shown in FIG. 9G in a fin plane 150 and in FIG. 9H in a carrier plane 160. The fabricator removes (e.g., via a chemical/mechanical etching process) a portion of the second channel region 115b where the source/drain regions 630c-d are to be formed, and may form additional layers of the encapsulation material 620 to conform around the gate 930, the second channel region 115b, and the intermediary insulator 120 on at least three sides. In various embodiments, the fabricator may apply additional layers of the insulator 120 and planarize the newly added insulator 120 with the upper surface of the encapsulation material 620, such as is shown in FIG. 9I in a fin plane 150 and in FIG. 9J in a carrier plane 160.

At block 850, the fabricator forms the contacts 940a-c (generally or collectively, contacts 940) for the gate 930 and the source/drain regions 630c-d for the second FET 110b, such as those shown in FIG. 9K in a fin plane 150 and in FIG. 9L in a carrier plane 160. In various embodiments, the fabricator may use different arrangements of contacts 940 that those shown in FIGS. 9K-9P, such as those shown in relation to FIGS. 2A-2E and 3A-3D, which may include different numbers of contacts 940 disposed in contact with different elements of the FETs 110. The fabricator etches cavities through the insulator 120, encapsulation material 620, and the source/drain regions 630c-d and fills the cavities with a conductive metal to form the contacts 940.

At block 860, the fabricator bonds a second control wafer 950 to the second FET 110b, such as that shown in FIG. 9M in a fin plane 150 and in FIG. 9N in a carrier plane 160. After bonding the second control wafer 950, the fabricator flips the structure to continue work on the opposite side of the structure. In various embodiments, the fabricator removes the first control wafer 650 after flipping the structure, but may retain the first control wafer 650 in other embodiments.

At block 870, the fabricator forms the contacts 940d-f for the gate 640 and the source/drain regions 630a-b for the first FET 110a, such as those shown in FIG. 9O in a fin plane 150 and in FIG. 9P in a carrier plane 160. In various embodiments, the fabricator may use different arrangements of contacts 940 that those shown in FIGS. 9K-9P, such as those shown in relation to FIGS. 2A-2E and 3A-3D, which may include different numbers of contacts 940 disposed in contact with different elements of the FETs 110. The fabricator etches cavities through the insulator 120, encapsulation material 620, and the source/drain regions 630a-b and fills the cavities with a conductive metal to form the contacts 940.

Accordingly, the fabricator has produced a stacked FET structure that includes a first FET 110a aligned on a first axis with a second FET 110b located on opposite sides of a plane perpendicular to the first axis, having a first power rail connected to the first FET 110a along the first axis and a second power rail connected to the second FET 110b along the first axis. Method 800 may then conclude, or the fabricator may perform additional tasks related to the structure, including adding additional layers of insulator 120, further control wafers, or the like.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, microcode, etc.) or an embodiment combining software and hardware aspects that may all generally be referred to herein as a “circuit,” “module” or “system.”

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to embodiments of the present invention, other and further embodiments of the invention may be devised without departing from the basic scope thereof, and the scope thereof is determined by the claims that follow.

What is claimed is:

1. A device, comprising:
a first power rail;
a second power rail;
a first Field Effect Transistor (FET) having a first gate connected to the first power rail;
a second FET having a second gate connected to the second power rail; and
an insulator separating the first FET from the second FET, wherein the first power rail, the second power rail, the first FET, and the second FET are aligned on a shared axis, and wherein the first power rail and the second power rail are located on opposite sides of the device.

2. The device of claim 1, wherein a first resistance between the first power rail and the first FET is substantially equal to a second resistance between the second power rail and the second FET.

3. The device of claim 1, wherein the first power rail and the second power rail are disposed at a cell boundary.

4. The device of claim 1, wherein the first FET is an n-type transistor and the second FET is a p-type transistor.

5. The device of claim 1, wherein the first FET includes a first source contact and a first drain contact and wherein the second FET includes a second source contact and a second drain contact.

6. The device of claim 5, wherein one of the first source contact and the second source contact or the first drain contact and second drain contact is provided as a shared contact for the first FET and the second FET.

7. The device of claim 1, wherein the device comprises a stacked arrangement, wherein the first power rail is on a top side of the stacked arrangment, and wherein the second power rail is on a bottom side of the stacked arrangement.

8. The device of claim 1, wherein the first FET and the second FET are one of FinFET transistor or nanosheet transistors.

9. A method, comprising:
forming a first channel region projecting in a first direction from a central insulator;
forming a first gate on the first channel region to define a first Field Effect Transistor (FET);
forming a second channel region projecting in a second direction, opposite to the first direction, from the central insulator; and
forming a second gate on the second channel region to define a second FET.

10. The method of claim 9, wherein forming the first gate further comprises:
forming a temporary gate around the first channel region;
forming a source contact and a drain contact connected on opposite sides on the first channel region; and
replacing the temporary gate with a gate metal.

11. The method of claim 9, wherein forming the first gate further comprises:
forming a gate metal around the first channel region; and
forming a source contact and a drain contact on opposite sides of the first channel region.

12. The method of claim 9, further comprising:
forming a first electrical contact for the first gate; and
forming a second electrical contact with the second gate, wherein the first electrical contact, the second electrical contact, the first FET, and the second FET are aligned on a shared axis.

13. The method of claim 9, further comprising:
after defining the first FET and before forming the second channel region:
bonding a first side of a die including the first FET to a first control wafer; and
flipping the die; and
after forming the second FET:
bonding a second side of the die, opposite to the first side, to a second control wafer.

14. The method of claim 9, wherein the first FET and the second FET comprise nanosheet transistors.

15. A device, comprising:
a first Field Effect Transistor (FET) aligned on a first axis with a second FET located on opposite sides on a plane perpendicular to the first axis;
a first power rail connected to the first FET along the first axis; and
a second power rail connected to the second FET along the first axis, wherein the first power rail and the second power rail are located on opposite sides of the device.

16. The device of claim 15, further comprising:
an insulator separating the first FET from the second FET, wherein the first FET projects in a first direction from the insulator and the second FET projects in a second direction, opposite to the first direction, from the insulator.

17. The device of claim 15, wherein a first contact connecting the first power rail to the first FET has a first resistance value and the second contact connecting the second FET to the second power rail has the first resistance value.

18. The device of claim 15, wherein the first FET is an nfet transistor and the second FET is pfet transistor.

19. The device of claim 15, the device comprises a stacked arrangement, wherein the first power rail is on a top side of the stacked arrangment, and wherein the second power rail is on a bottom side of the stacked arrangement.

20. The device of claim 15, wherein the first FET and the second FET are one of FinFET transistor or nanosheet transistors.
